(19) United States
(12) Patent Application Publication
(10) Pub. No.: US 2024/0110985 A1
(43) Pub. Date: Apr. 4, 2024

(54) METHOD AND APPARATUS FOR MONITORING BATTERY CELL DATA, STORAGE MEDIUM, AND ELECTRONIC DEVICE

(71) Applicants: Shanghai Makesens Energy Storage Technology Co., Ltd., Shanghai (CN); Shanghai Volta Institute of Digital Battery Energy Storage, Shanghai (CN)

(72) Inventors: Zhimin ZHOU, Shanghai (CN); Pingchao HAO, Shanghai (CN); Zhou YANG, Shanghai (CN); Jie ZHANG, Shanghai (CN); Xuesi ZHANG, Shanghai (CN); Enhai ZHAO, Shanghai (CN); Xiao YAN, Shanghai (CN)

(73) Assignees: Shanghai Makesens Energy Storage Technology Co., Ltd., Shanghai (CN); Shanghai Volta Institute of Digital Battery Energy Storage, Shanghai (CN)

(21) Appl. No.: 18/370,407

(22) Filed: Sep. 20, 2023

(30) Foreign Application Priority Data
Sep. 29, 2022 (CN) 2022112039543

(51) Int. Cl. G01R 31/367; G01R 31/396

(52) U.S. Cl. CPC G01R 31/367; G01R 31/396

(57) ABSTRACT

A method for monitoring battery cell data comprises: collecting the first set of the battery cell data in real time; retrieving estimation parameter data corresponding to the first set of the battery cell data from a battery cell parameter database in real time; based on the estimation parameter data of the first set of the battery cell data, processing the first set of the battery cell data through a battery model to acquire the second set of the battery cell data in real time; acquiring an error value between the first set and the second set of the battery cell data in real time; acquiring a monitoring result of the first set of the battery cell data in real time based on the error value and an error threshold, the monitoring result is either the error value being greater than the error threshold, or less than the error threshold.

### CROSS REFERENCE TO RELATED APPLICATION

The present application claims the benefit of priority to Chinese Patent Application No. CN 202211203954.3, entitled “METHOD AND APPARATUS FOR MONITORING BATTERY CELL DATA, STORAGE MEDIUM, AND ELECTRONIC DEVICE”, filed with CNIPA on Sep. 29, 2022, the disclosure of which is incorporated herein by reference in its entirety for all purposes.

### FIELD OF THE INVENTION

The present disclosure generally relates to the technical field of batteries, in particular to a method and an apparatus for monitoring battery cell data, a storage medium, and an electronic device.

### BACKGROUND OF THE INVENTION

In recent years, due to their unique advantages, lithium-ion batteries have emerged as the leading battery technology for energy storage stations in many countries. To ensure their safe operation, it's crucial to continuously monitor data from these batteries to prevent issues such as over-discharge, over-charge, over-heating, and degradation, etc. Typically, estimation of parameters in such data is performed based on collected battery cell data from actual battery cells, which is necessary for initiating a battery model in order to obtain the simulated data. By calculating the error between the simulated data and the collected battery data, it can be determined whether there are any abnormalities in the actual battery cells. However, the process of parameter estimation requires a certain amount of time, leading to a lower monitoring efficiency, making real-time monitoring challenging to achieve.

### SUMMARY OF THE INVENTION

A first aspect of the present disclosure provides a method for monitoring battery cell data, comprising: collecting first set of the battery cell data from the first battery in real time; retrieving estimation parameter data corresponding to the first set of the battery cell data from a battery cell parameter database in real time based on the first set of the battery cell data; based on the estimation parameter data corresponding to the first set of the battery cell data, processing the first set of the battery cell data through a battery model to acquire second set of the battery cell data in real time; acquiring an error value between the first set of the battery cell data and the second set of the battery cell data in real time; acquiring a monitoring result of the first set of the battery cell data in real time based on the error value and a predetermined error threshold, wherein the monitoring result is that the error value is greater than the error threshold, or that the error value is less than the error threshold.

A second aspect of the present disclosure provides an apparatus for monitoring battery cell data, comprising: a first-battery-cell-data acquisition module, for collecting first set of the battery cell data in real time; an estimation-parameter-data acquisition module, for retrieving estimation parameter data corresponding to the first set of the battery cell data from a battery cell parameter database in real time based on the first set of the battery cell data; a second-battery-cell data acquisition module, for processing the estimation parameter data corresponding to the first set of the battery cell data through the battery model to acquire second set of the battery cell data in real time; a data-error-value acquisition module, for acquiring an error value between the first set of the battery cell data and the second set of the battery cell data in real time; a monitoring-result acquisition module, for acquiring a monitoring result of the first set of the battery cell data in real time based on the error value and an error threshold, wherein the monitoring result is that the error value is greater than the error threshold, or that the error value is less than the error threshold.

A third aspect of the present disclosure provides a non-transitory computer-readable storage medium, which stores a computer program, wherein when the computer program is executed by a processor, the method for monitoring battery cell data described above is implemented.

A fourth aspect of the present disclosure provides an electronic device, comprising: a memory, on which a computer program is stored; and a processor, communicatively connected to the memory and configured to call the computer program to perform the method for monitoring battery cell data described above.

In summary, the method and apparatus for monitoring battery cell data, the medium, and the electronic device disclosed above have the following beneficial effects:

Unlike existing technologies, which first estimate parameters of the actual working cells based on collected battery cell data and then initiate a battery model based on the results of parameter estimation, the present method disclosed directly retrieves estimation parameter data acquired from collected battery cell data from a battery cell parameter database in real time and initiates a battery model based on the estimation parameter data. This approach eliminates the need for real-time parameter estimation for the cells, thereby improving monitoring efficiency and achieving real-time monitoring of the collected battery cell data.

Moreover, by integrating cell data monitoring with database technology, the present disclosed method proves to be more adaptable to various battery industrial environments compared to conventional monitoring methods. Therefore, the present disclosure holds great practical value in real-world applications.

### BRIEF DESCRIPTION OF THE DRAWINGS

FIG. 1 shows a flowchart illustrating a method for monitoring battery cell data according to one embodiment of the present disclosure.

FIG. 2 shows a flowchart of updating a battery cell parameter database according to one embodiment of the present disclosure.

FIG. 3 shows a flowchart of updating a battery cell parameter database according to one embodiment of the present disclosure.

FIG. 4 shows a flowchart of processing the first set of the battery cell data through a battery model according to one embodiment of the present disclosure.

FIG. 5 shows a flowchart of constructing a battery cell parameter database according to one embodiment of the present disclosure.

FIG. 6 shows a block diagram of an apparatus for monitoring battery cell data according to one embodiment of the present disclosure.

FIG. 7 shows a block diagram of an electronic device according to one embodiment of the present disclosure.

### REFERENCE NUMERALS

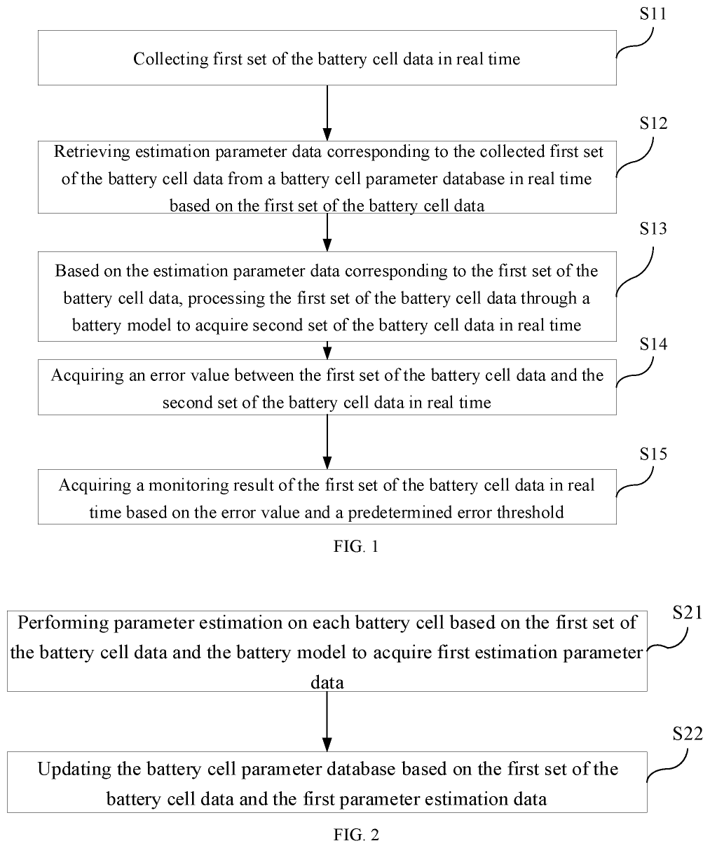

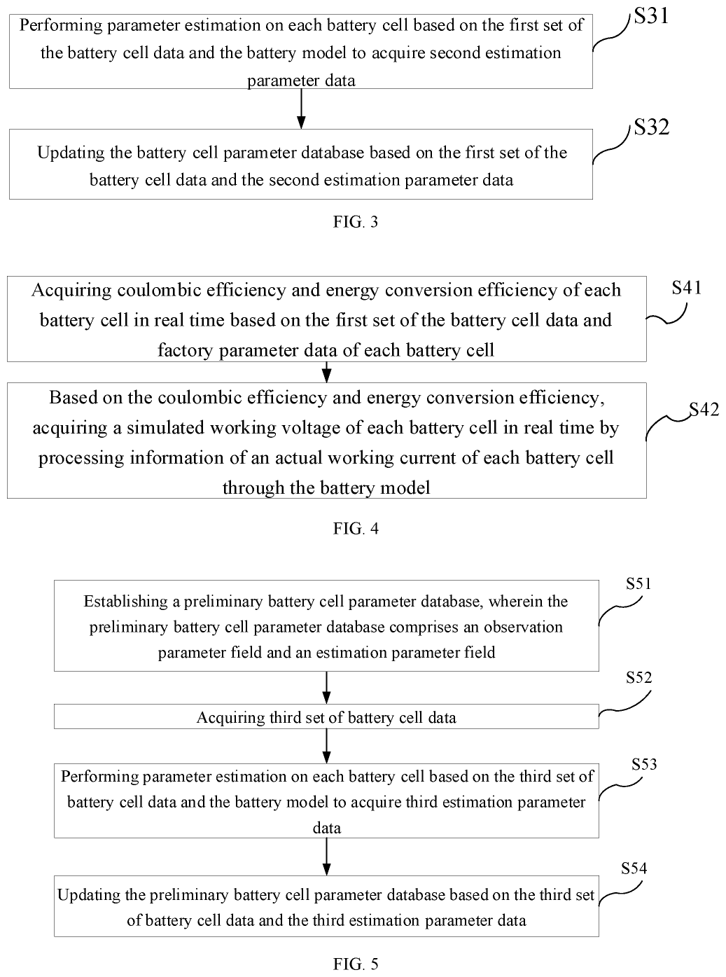

600 Apparatus for Monitoring Battery Cell Data
610 First-Battery-Cell-Data Acquisition Module
620 Estimation-Parameter-Data Acquisition Module
630 Second-Battery-Cell-Data Acquisition Module
640 Data-Error-Value Acquisition Module
650 Monitoring-Result Acquisition Module
700 Electronic Device
710 Memory
720 Processor
S11-S15 Various Steps in FIG. 1
S21-S22 Various Steps in FIG. 2
S31-S32 Various Steps in FIG. 3
S41-S42 Various Steps in FIG. 4
S51-S54 Various Steps in FIG. 5

### DETAILED DESCRIPTION

The embodiments of the present disclosure will be described below. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure. It needs to be stated that the following embodiments and the features in the embodiments can be combined with one another under the situation of no conflict.

It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during actual implementation thereof may be freely changed, and the component layout configuration thereof may be more complex.

In recent years, due to their unique advantages, lithium-ion batteries have emerged as the leading technology for energy storage stations in many countries, for example, China. To ensure their safe operation, it's crucial to continuously monitor data from these batteries to prevent issues such as over-discharge, over-charge, over-heating, and degradation. Typically, parameter estimation is performed on actual battery cells based on collected battery cell data, which is necessary for initiating a battery model and obtain simulated data. By calculating an error between the simulated data and the collected data, it can be determined whether there are any abnormalities in the actual battery cells. However, the process of parameter estimation requires a certain amount of time, leading to a lower monitoring efficiency, making real-time monitoring challenging to achieve. In light of the above problems, the present disclosure provides a method for monitoring battery cell data, which comprises: collecting first set of the battery cell data in real time; acquiring estimation parameter data corresponding to the first set of the battery cell data in a battery cell parameter database in real time based on the first set of the battery cell data; based on the estimation parameter data corresponding to the first set of the battery cell data, processing the first set of the battery cell data through a battery model to acquire second set of the battery cell data in real time; acquiring an error value between the first set of the battery cell data and the second set of the battery cell data in real time; acquiring a monitoring result of the first set of the battery cell data in real time based on the error value and an error threshold, wherein the monitoring result is that the error value is greater than the error threshold, or that the error value is less than the error threshold. Unlike an existing technology, which estimates parameters of the actual working cells based on prior collected battery cell data and then initiates a battery model based on results of parameter estimation, the present disclosed method directly retrieves estimation parameter data corresponding to collected battery cell data from a battery cell parameter database in real time and initiates a battery model based on the estimation parameter data. This approach eliminates the need for real-time parameter estimation for the cells, thereby improving monitoring efficiency and achieving real-time monitoring of the collected battery cell data.

Moreover, by integrating cell data monitoring with database technology, the present disclosed method proves to be more adaptable to various battery industrial environments compared to conventional monitoring methods. Therefore, the present disclosure holds greater practical value in real-world applications.

As an example, the method for monitoring battery cell data comprises steps S11-S15:

S11: collecting first set of the battery cell data in real time.

Exemplarily, collecting the first set of the battery cell data comprises: collecting the first set of the battery cell data of actual working batteries in real time through a battery management system; and receiving the collected first set of the battery cell data in real time. The actual working batteries may include multiple cell-batteries, and the first set of the battery cell data may have one or more of an actual working voltage, actual working current, actual working temperature, actual residual capacity, and actual health level of each battery cell.

S12: retrieving estimation parameter data corresponding to the collected first set of the battery cell data from a battery cell parameter database in real time based on the first set of the battery cell data.

Exemplarily, the battery cell parameter database comprises a parameter data table for each battery cell, and the battery cell parameter database at least comprises an observation parameter field and an estimation parameter field, wherein the observation parameter field may be represented by {V, i, SOC}, wherein V represents the actual working voltage, i represents the actual working current, and SOC represents the actual residual capacity. The estimation parameters refer to parameters that cannot be directly collected by the battery management system, such as an effective area of a positive electrode plate, an effective thickness of the positive electrode plate, and the like. For each piece of the first set of the battery cell data, one piece of the estimation parameter data can be acquired through parameter estimation; that is, the estimation parameter data correspond to the first set of the battery cell data. For example, when the first set of the battery cell data indicates that the working voltage is 3.4V, the effective thickness of the positive electrode plate can be estimated to be about 60 microns through parameter estimation.

Exemplarily, the parameter estimation can be realized by means of a genetic algorithm.

Exemplarily, data stored in the battery cell parameter database comprise observation parameter data (obtained through experimental measurements) and estimation parameter data, and the robustness of the method for monitoring battery cell data increases as more relevant data is gathered through experimental measurements. In addition, when there is not enough data gathered through experimental measurements, observation parameter data under different working conditions can be first acquired, which are then used to obtain estimation parameter data under different working conditions through parameter estimation, so as to supplement the battery cell parameter database.

S13: based on the estimation parameter data corresponding to the first set of the battery cell data, processing the first set of the battery cell data through a battery model to acquire second set of the battery cell data in real time.

Exemplarily, the battery model may be a battery electrochemical model, and the second set of the battery cell data may comprise one or more of a simulated working voltage, simulated working current, simulated working temperature, simulated residual capacity, and simulated health data of each battery cell. Processing the first set of the battery cell data through the battery model comprises: adding the estimation parameter data corresponding to the first set of the battery cell data to the battery model, and processing the first set of the battery cell data through the battery model to acquire the second set of the battery cell data in real time. For example, by processing the actual working current of each battery cell through the battery model, the simulated working voltage of each battery cell can be acquired. In addition, in the process of acquiring the second set of the battery cell data in real time, factory parameter data of each battery cell is also needed, and the factory parameter data of each battery cell can be found in the product manual of each battery cell.

S14: acquiring an error value between the first set of the battery cell data and the second set of the battery cell data in real time.

Exemplarily, the error value of the first set of the battery cell data and the second set of the battery cell data may be the absolute value of the difference between the first set of the battery cell data and the second set of the battery cell data.

S15: acquiring a monitoring result of the first set of the battery cell data in real time based on the error value and a predetermined error threshold, wherein the monitoring result can be either that the error value is greater than the error threshold, or the error value is less than the error threshold. In some cases, the error threshold may be adjusted according to actual needs.

As described above, the present disclosed method for monitoring battery cell data comprises: collecting the first set of the battery cell data in real time; acquiring estimation parameter data based on the first set of the battery cell data in a battery cell parameter database in real time first set of the battery cell data; based on the estimation parameter data corresponding to the first set of the battery cell data, processing the first set of the battery cell data through a battery model to acquire the second set of the battery cell data in real time; acquiring an error value between the first set of the battery cell data and the second set of the battery cell data in real time; acquiring a monitoring result of the first set of the battery cell data in real time based on the error value and an error threshold, wherein the monitoring result can be either the error value being greater than the error threshold, or less than the error threshold. Unlike the existing technology, which first estimates parameters of the actual working cells based on prior collected battery cell data and then initiates a battery model based on results of the parameter estimation, the present disclosed method directly retrieves estimation parameter data corresponding to collected battery cell data from a battery cell parameter database in real time and initiates a battery model based on the estimation parameter data instantaneously. This approach eliminates the need for real-time parameter estimation for the cells, thereby improving monitoring efficiency and achieving real-time monitoring of the collected battery cell data.

Moreover, by integrating cell data monitoring with database technology, the present disclosed method proves to be more adaptable to various industrial environments of batteries compared to any conventional monitoring methods. Therefore, the present disclosure holds greater practical value in real-world applications.

Referring to FIG. 2, as an example, the method for monitoring battery cell data further comprises steps S21 and S22:

S21: performing parameter estimation on each battery cell based on the first set of the battery cell data and the battery model to acquire first estimation parameter data.

S22: updating the battery cell parameter database based on the first set of the battery cell data and the first parameter estimation data.

Due to variations in the parameters of the battery cells from manufacturing, the data stored in the battery cell parameter database may have an accuracy range. So, the battery model relying on these estimation parameters stored in the battery cell parameter database for its operation may thus also contain uncertainty. To ensure that the battery model more accurately reflects real-world conditions upon startup, the present disclosure introduces a calibrating procedure and updates the battery cell parameter database, the procedure comprises: performing parameter estimation on each battery cell based on the first set of the battery cell data and the battery model to acquire second estimation parameter data; and updating the battery cell parameter database based on the first set of the battery cell data and the first estimation parameter, enhancing the reliability of the data stored in the battery cell parameter database.

Referring to FIG. 3, as an example, when the monitoring result is first the error value is greater than the error threshold for one or more times, and second, the number of times the error value has been greater than the error threshold is less than a preset number, the method further comprises steps S31 and S32.

S31: performing parameter estimation on each battery cell based on the first set of the battery cell data and the battery model to acquire second estimation parameter data. It should be noted that the steps shown in FIG. 3 are slightly different from those shown in FIG. 2. In FIG. 2, the parameter estimation is carried out because there are variations in the parameters of the battery cells from manufacturing, and the data stored in the battery parameter database may have significant errors, so the corresponding steps are equivalent to preprocessing before actually monitoring the operation of the battery, that is, performing parameter estimation based on data such as actual working voltages of the battery cells in order to calibrate and update the battery parameter database. However, the steps shown in FIG. 3 are for parameter estimation based on the first set of the battery cell data when the error value of the monitoring result is relatively large. The steps in FIG. 2 and FIG. 3 are from different scenarios and different solutions. For the clarity, the estimation parameter data acquired in S31 is referred to as the second estimation parameter data, and the estimation parameter data acquired in S21 is referred to as the first estimation parameter data.

S32: updating the battery cell parameter database based on the first set of the battery cell data and the second estimation parameter data.

Exemplarily, if the error value is less than the error threshold, the first set of the battery cell data will not be subject to parameter estimation, and the first set of the battery cell data and the estimation parameter data corresponding to the first set of the battery cell data will be directly stored in the battery cell parameter database. It should be noted that when retrieving the estimation parameter data corresponding to the first set of the battery cell data from the battery cell parameter database, the corresponding battery cell parameter data table is generally queried according to the actual working voltage of the battery cell. The battery cell parameter table contains data that matches the actual working voltage of the battery cell, if each data entry has multiple parameters, and there might be differences in other parameters, such as the actual working temperature of the battery cell. Therefore, the first set of the battery cell data and the estimation parameter data corresponding to the first set of the battery cell data can be stored in the battery cell parameter database to expand the range of data available in the database.

Exemplarily, when the monitoring result is that the error value is greater than the error threshold, and the number of times the error value has been greater than the error threshold is greater than a preset number, the method further comprises sending out a warning signal. The warning signal may be a control signal that a computer uses to control an alarm. Specifically, the computer may be electrically connected with the alarm, and the alarm will issue a warning after receiving the control signal.

Because errors in the data in the battery cell parameter database are almost inevitable, in actual application scenarios, if the actual working battery cells are determined to have an anomaly once the first set of the battery cell data has a monitoring anomaly, this may lead to a waste of resources due to false alarms. To avoid wasting resources, we may have a preset number, and when the number of times the error value is greater than the error threshold is less than the preset number, the data in the battery cell parameter database can be deemed to have no errors and can be updated as usual. In the present disclosure, by performing parameter estimation on each battery cell based on the first set of the battery cell data and the battery model to acquire second estimation parameter data; and updating the battery cell parameter database based on the first set of the battery cell data and the second estimation parameter, timely updating the data in the battery cell parameter database without wasting resources can be achieved.

Referring to FIG. 4, as an example, processing the first set of the battery cell data through the battery model comprises steps S41 and S42.

S41: acquiring coulombic efficiency and energy conversion efficiency of each battery cell in real time based on the first set of the battery cell data and factory parameter data of each battery cell. The factory parameter data of each battery cell can be found in the product manual of each battery cell.

S42: based on the coulombic efficiency and energy conversion efficiency, acquiring a simulated working voltage of each battery cell in real time by processing information of an actual working current of each battery cell through the battery model. The coulombic efficiency and the energy conversion efficiency may be used as coefficients of the actual working current, and the simulated working voltage may be acquired by real-time calculations based on the actual working current, the coulombic efficiency, and the energy conversion efficiency through the battery model.

In summary, processing the first set of the battery cell data through the battery model comprises: acquiring the coulombic efficiency and energy conversion efficiency of each battery cell in real time based on the first set of the battery cell data and the factory parameter data of each battery cell; and based on the coulombic efficiency and energy conversion efficiency, acquiring the simulated working voltage of each battery cell in real time by processing the information of the actual working current of each battery cell through the battery model. In this way, the simulated working voltage can be acquired in real time, thereby realizing real-time voltage monitoring and real-time voltage tracking.

Referring to FIG. 5, as an example, constructing the battery cell parameter database comprises steps S51 to S54.

S51: establishing a preliminary battery cell parameter database, wherein the preliminary battery cell parameter database comprises an observation parameter field and an estimation parameter field;

Optionally, the method further comprises: establishing a single-column index of the observation parameter field and a joint index of the observation parameter field and the estimation parameter field. By establishing the single-column index of the observation parameter field and the joint index of the observation parameter field and the estimation parameter field, the efficiency of retrieving data from the battery cell parameter database during the monitoring process can be improved.

Optionally, the method further comprises: inserting the observation parameter data (obtained through experimental measurements) and the estimation parameter data into the preliminary battery cell parameter database. The preliminary battery cell parameter database may refer to a battery cell parameter database which does not contain observation parameter data and estimation parameter data, or a battery cell parameter database which only contains observation parameter data (obtained through experimental measurements) and estimation parameter data.

S52: acquiring third set of battery cell data. The third set of battery cell data may comprise data such as working voltages and working currents of each battery cell under different working conditions. To avoid not being able to retrieve data matching the first set of the battery cell data from the preliminary cell parameter database during the monitoring process of the first set of the battery cell data, the preliminary cell parameter database may be expanded based on the third set of battery cell data.

S53: performing parameter estimation on each battery cell based on the third set of battery cell data and the battery model to acquire third estimation parameter data. Details of the parameter estimation may be found in descriptions of the first set of the battery cell data and the first estimation parameter data.

S54: updating the preliminary battery cell parameter database based on the third set of battery cell data and the third estimation parameter data.

The observation parameter data (obtained through experimental measurements) and their corresponding estimation parameter data are likely to have a limited volume, resulting in a low data range and a low data density, which may lead to frequent failures when retrieving matching data from the battery parameter database during the monitoring process. The robustness of battery cell data monitoring can be improved by expanding the preliminary battery cell parameter database through introducing the third set of battery cell data and the third estimation parameter data.

The present disclosure further provides an apparatus for monitoring battery cell data 600. Specifically, referring to FIG. 6, the apparatus for monitoring battery cell data 600 comprises:
a first-battery-cell-data acquisition module 610, for collecting first set of the battery cell data in real time;
an estimation-parameter-data acquisition module 620, for retrieving estimation parameter data corresponding to the first set of the battery cell data from a battery cell parameter database in real time based on the first set of the battery cell data;
a second-battery-cell data acquisition module 630, for processing the estimation parameter data corresponding to the first set of the battery cell data through the battery model to acquire second set of the battery cell data in real time;
a data-error-value acquisition module 640, for acquiring an error value between the first set of the battery cell data and the second set of the battery cell data in real time; and
a monitoring-result acquisition module 650, for acquiring a monitoring result of the first set of the battery cell data in real time based on the error value and an error threshold, wherein the monitoring result is that the error value is greater than the error threshold, or that the error value is less than the error threshold.

Unlike any existing technology, which estimates parameters of the actual working cells based on collected battery cell data and then initiates a battery model based on results of parameter estimation, the present disclosed apparatus directly retrieves estimation parameter data corresponding to collected battery cell data from a battery cell parameter database in real time and initiates a battery model based on the estimation parameter data. This approach eliminates the need for real-time parameter estimation for the cells, thereby improving monitoring efficiency and achieving real-time monitoring of the collected battery cell data.

Moreover, by integrating cell data monitoring with database technology, the present disclosed apparatus proves to be more adaptable to various battery industrial environments compared to conventional monitoring methods. Therefore, the present disclosure holds greater practical value in real-world applications.

Based on the above-described method for monitoring battery cell data, the present disclosure further provides a non-transitory computer-readable storage medium storing a computer program. The computer program, when executed by a processor, implements the method for monitoring battery cell data as shown in FIG. 1.

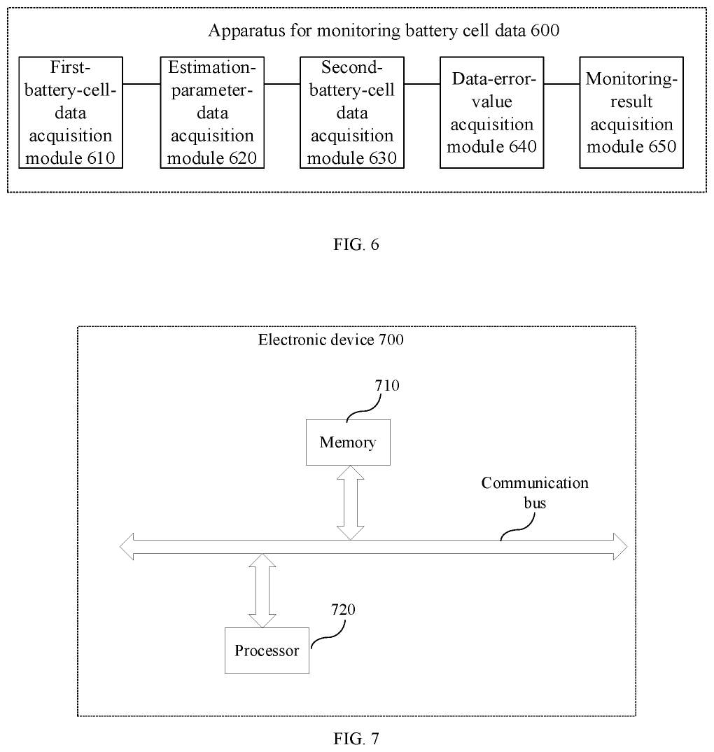

Based on the above-described method for monitoring battery cell data, the present disclosure further provides an electronic device. Refer to FIG. 7. As an example, the electronic device 700 comprises a memory 710, on which a computer program is stored; a processor 720, communicatively connected with the memory 710, and configured to call the computer program to perform the method for monitoring battery cell data as shown in FIG. 1.

The scope of the method for monitoring battery cell data as described in the present disclosure is not limited to the sequence of operations listed. Any scheme realized by adding or subtracting operations or replacing operations of the traditional techniques according to the principle of the present disclosure is included in the scope of the present disclosure.

The present disclosed method and apparatus for monitoring battery cell data, storage medium, and electronic device realize real-time monitoring of battery cell data. Therefore, the present disclosure effectively overcomes various shortcomings of the prior art and has a high industrial value.

The above-mentioned embodiments are merely illustrative of the principle and effects of the present disclosure instead of restricting the scope of the present disclosure. Modifications or variations of the above-described embodiments may be made by those skilled in the art without departing from the spirit and scope of the disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for monitoring battery cell data, comprising:
collecting a first set of the battery cell data in real time;
retrieving estimation parameter data based on the first set of the battery cell data from a battery cell parameter database in real time;
based on the estimation parameter data based on the first set of the battery cell data, processing the first set of the battery cell data through a battery model to acquire second set of the battery cell data in real time;
acquiring an error value between the first set of the battery cell data and the second set of the battery cell data in real time; and
acquiring a monitoring result of the first set of the battery cell data in real time based on the error value and an error threshold, wherein the monitoring result is either the error value being greater than the error threshold, or being less than the error threshold.

2. The method according to claim 1, wherein the estimation parameter data comprises first estimation parameter data, wherein the method further comprises:
performing parameter estimation on each battery cell based on the first set of the battery cell data and the battery model to acquire the first estimation parameter data; and
updating the battery cell parameter database based on the first set of the battery cell data and the first estimation parameter data.

3. The method according to claim 1, wherein when the monitoring result is that the error value is greater than the error threshold, and the number of times the error value has been greater than the error threshold is less than a preset number, the estimation parameter data comprises second estimation parameter data, and wherein the method further comprises:
performing parameter estimation on each battery cell based on the first set of the battery cell data and the battery model to acquire the second estimation parameter data; and
updating the battery cell parameter database based on the first set of the battery cell data and the second estimation parameter data.

4. The method according to claim 3, wherein when the monitoring result is that the error value is greater than the error threshold, and the number of times the error value has been greater than the error threshold is greater than a preset number, the method further comprises sending out a warning signal.

5. The method according to claim 1, wherein processing the first set of the battery cell data through the battery model comprises:
acquiring coulombic efficiency and energy conversion efficiency of each battery cell in real time based on the first set of the battery cell data and factory parameter data of each battery cell; and
based on the coulombic efficiency and energy conversion efficiency, acquiring a simulated working voltage of each battery cell in real time by processing information of an actual working current of each battery cell through the battery model.

6. The method according to claim 1, the battery cell parameter database is constructed by:
establishing a preliminary battery cell parameter database, wherein the preliminary battery cell parameter database comprises an observation parameter field and an estimation parameter field;
acquiring third set of battery cell data third set of battery cell data;
performing parameter estimation on each battery cell based on the third set of battery cell data and the battery model to acquire third estimation parameter data of the estimation parameter data based on the first set of the battery cell data; and
updating the preliminary battery cell parameter database based on the third set of battery cell data and the third estimation parameter data.

7. The method according to claim 6, further comprising: establishing a single-column index of the observation parameter field and a joint index of the observation parameter field and the estimation parameter field.

8. An apparatus for monitoring battery cell data of a battery cell, comprising:
a first-battery-cell-data acquisition module, which collects a first set of the battery cell data in real time;
an estimation-parameter-data acquisition module, which retrieves estimation parameter data corresponding to the first set of the battery cell data from a battery cell parameter database in real time based on the first set of the battery cell data;
a second-battery-cell data acquisition module, which processes the estimation parameter data corresponding to the first set of the battery cell data through a battery model to acquire second set of the battery cell data in real time;
a data-error-value acquisition module, which acquires an error value between the first set of the battery cell data and the second set of the battery cell data in real time; and
a monitoring-result acquisition module, which acquires a monitoring result of the first set of the battery cell data in real time based on the error value and an error threshold, wherein the monitoring result is either the error value being greater than the error threshold, or being less than the error threshold.

9. A non-transitory computer-readable storage medium, storing a computer program, wherein when the computer program is executed by a processor, the method for monitoring the battery cell data according to claim 1 is implemented.

10. An electronic device, comprising:
a memory, comprising a computer program; and
a processor, communicatively connected to the memory, wherein the processor controls the computer program to perform the method for monitoring the battery cell data according to claim 1.
